(19) United States
(12) Patent Application Publication
(10) Pub. No.: US 2024/0258085 A1
(43) Pub. Date: Aug. 1, 2024

(54) SHARED EXHAUST UNIT AND SUBSTRATE PROCESSING APPARATUS INCLUDING SHARED EXHAUST UNIT

(71) Applicant: ASM IP Holding B.V., Almere (NL)

(72) Inventor: Koei Aida, Tokyo (JP)

(21) Appl. No.: 18/420,983

(22) Filed: Jan. 24, 2024

Related U.S. Application Data
(60) Provisional application No. 63/441,588, filed on Jan. 27, 2023.

(51) Int. Cl. H01J 37/32; C23C 16/44; C23C 16/455; C23C 16/458; C23C 16/52

(52) U.S. Cl. CPC H01J 37/32834; C23C 16/4412; C23C 16/45544; C23C 16/45565; C23C 16/4583; C23C 16/52; H01J 37/32449; H01J 37/32899; H01J 2237/332

(57) ABSTRACT

A substrate processing apparatus is disclosed. Exemplary substrate processing apparatus includes a plurality of reaction chambers; a gas supply unit configured to provide the reaction chamber with a main gas; a shared exhaust unit configured to exhaust the main gas from the plurality of reaction chambers; a plurality of exhaust gas lines configured to fluidly couple the shared exhaust unit to the plurality of reaction chambers; and a plurality of dilution gas lines configured to provide a dilution gas into the plurality of exhaust gas lines.

### CROSS-REFERENCE TO RELATED APPLICATIONS

This application claims priority to U.S. Provisional Patent Application Ser. No. 63/441,588 filed Jan. 27, 2023 titled SHARED EXHAUST UNIT AND SUBSTRATE PROCESSING APPARATUS INCLUDING SHARED EXHAUST UNIT, the disclosure of which is hereby incorporated by reference in its entirety.

### FIELD OF INVENTION

The present disclosure relates generally to a shared exhaust unit. More particularly, exemplary embodiments of the present disclosure relate to a shared exhaust unit and a substrate processing apparatus including the shared exhaust unit.

### BACKGROUND OF THE DISCLOSURE

In order to increase throughput of processed wafers, multiple wafers are loaded in a reaction chamber and processed simultaneously, by executing batch programs. However, it is difficult to perform processing with high precision using batch programs. On the other hand, if a single wafer is loaded in a reaction chamber and processed, the process can be controlled with high precision, but throughput suffers. If multiple reaction chambers of the single-wafer processing type share a common process and cleaning gas supply system and an exhaust system, simultaneous operation of the multiple reaction chambers may increase throughput. An exemplary substrate processing apparatus is disclosed in U.S. Pat. No. 9,447,498, which is hereby incorporated by reference.

However, when the multiple reaction chambers share an exhaust gas unit, cross talk through the exhaust line may occur when gate valves are open, thereby causing particles because the pressure of each reaction chamber may be different.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a substrate processing apparatus is provided. The substrate processing apparatus may comprise a plurality of reaction chambers; a gas supply unit configured to provide the reaction chamber with a main gas; a shared exhaust unit configured to exhaust the main gas from the plurality of reaction chambers; a plurality of exhaust gas lines configured to fluidly couple the shared exhaust unit to the plurality of reaction chambers; and a plurality of dilution gas lines configured to provide a dilution gas into the plurality of exhaust gas lines.

In various embodiments, the shared exhaust unit may comprise: a shared valve configured to control a flow rate of an exhaust gas; and a shared vacuum pump fluidly coupled to the shared valve.

In various embodiments, the substrate processing apparatus may further comprise a dilution gas valve configured to control a flow rate of the dilution gas.

In various embodiments, the flow rate of the dilution gas may be configured to be controlled to keep the shared valve open.

In various embodiments, the substrate processing apparatus may further comprise a seal gas line disposed in a bottom of the reaction chamber and configured to provide a seal gas into the reaction chamber.

In various embodiments, the dilution gas valve may be configured to control the flow rate of the dilution gas to exceed the total flow rate of the main gas and seal gas.

In various embodiments, the total flow rate of the dilution gas, the main gas, and the seal gas may be 100 sccm to 100 slm.

In various embodiments, the main gas may comprise a process gas, carrier gas, and dilution gas.

In various embodiments, the substrate processing apparatus may further comprise a gate valve connected to a wall of the reaction chamber.

In various embodiments, the substrate processing apparatus may further comprise a substrate transfer chamber connected to the gate valve.

In various embodiments, the substrate processing apparatus may further comprise a substrate transfer robot disposed within the substrate transfer chamber for transferring a substrate between the reaction chamber and the substrate transfer chamber through the gate valve.

In various embodiments, each gate valve may be configured to be opened when the substrate is being transferred from the substrate transfer chamber to the reaction chamber and vice versa.

In various embodiments, the substrate processing apparatus may further comprise a susceptor positioned within the reaction chamber to be constructed and arranged to support the substrate.

In various embodiments, the gas supply unit may comprise a shower plate to be constructed and arranged to face the susceptor.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 is a schematic plan view of a semiconductor processing apparatus with dual chamber modules usable in an embodiment of the present invention.

FIG. 2 is a schematic cross-sectional view of a dual chamber module in an embodiment of the present invention.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas, carrier gas, and dilution gas refer to a gas that does not take part in a chemical reaction to an appreciable extent and/or a gas that can excite a precursor when plasma power is applied.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

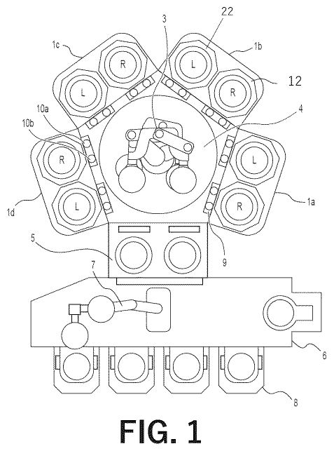

FIG. 1 is a schematic plan view of a substrate processing apparatus with dual chamber modules in an embodiment of the present invention. The substrate processing apparatus may comprise: (i) four process modules 1a-1d, each having two reaction chambers 12, 22 arranged side by side with their fronts aligned in a line; (ii) a substrate handling chamber 4 including two back end robots 3 (substrate handling robots); and (iii) a load lock chamber 5 for loading or unloading two substrates simultaneously, the load lock chamber 5 being attached to the one additional side of the substrate handling chamber 4, wherein each back end robot 3 is accessible to the load lock chamber 5. Each of the back end robots 3 has at least two end-effectors accessible to the two reaction chambers of each unit simultaneously, said substrate handling chamber 4 having a polygonal shape having four sides corresponding to and being attached to the four process modules 1a-1d, respectively, and one additional side for a load lock chamber 5, all the sides being disposed on the same plane. The interior of each reaction chamber 12, 22 and the interior of the load lock chamber 5 may be isolated from the interior of the substrate handling chamber 4 by a gate valve 9.

In some embodiments, a controller (not shown) may store software programmed to execute sequences of substrate transfer, for example. The controller may also: check the status of each reaction chamber; position substrates in each reaction chamber using sensing systems, control a gas box and an electric box for each module; control a front end robot 7 in an equipment front end module 6 based on a distribution status of substrates stored in FOUP 8 and a load lock chamber 5; control back end robots 3; and control gate valves 9 and other valves.

A skilled artisan may appreciate that the apparatus includes one or more controller(s) programmed or otherwise configured to cause the deposition and reactor cleaning processes described elsewhere herein to be conducted. The controller(s) may communicate with the various power sources, heating systems, pumps, robotics, gas flow controllers, or valves, as will be appreciated by the skilled artisan.

In some embodiments, the apparatus may have any number of reaction chambers and process modules greater than one (e.g., 2, 3, 4, 5, 6, or 7). In FIG. 1, the apparatus has eight reaction chambers, but it may have ten or more. In some embodiments, the reactors of the modules may be any suitable reactors for processing or treating wafers, including CVD reactors (such as plasma-enhanced CVD reactors and thermal CVD reactors) or ALD reactors (such as plasma-enhanced ALD reactors and thermal ALD reactors). Typically, the reaction chambers may be plasma reactors for depositing a thin film or layer on a wafer. In some embodiments, all the modules may be of the same type having identical capabilities for treating wafers so that the unloading/loading can sequentially and regularly be timed, thereby increasing productivity or throughput. In some embodiments, the modules may have different capabilities (e.g., different treatments) but their handling times may be substantially identical.

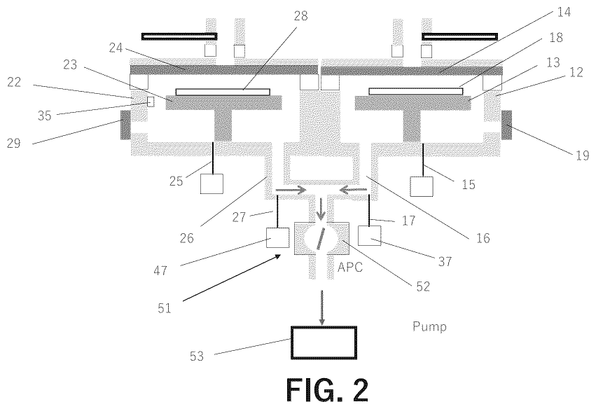

FIG. 2 is a schematic cross-sectional view of a dual chamber module in an embodiment of the present invention. In the reaction chamber 12, a gas supply unit comprising a shower plate 14 and a susceptor 13 may be provided, and in the reaction chamber 22, a gas supply unit comprising a shower plate 24 and a susceptor 23 may be provided. The susceptors 13, 23 may support substrates 18, 28 and be heated by an incorporated heater or an external heater, thereby controlling a temperature of the substrate.

Each shower plates 14, 24 may be constructed and arranged to face the susceptors 13, 23. The shower plates 14, 24 may be provided with a plurality of holes such a main gas including process gas, a carrier gas, and a dilution gas is supplied to the substrate placed on the susceptors 13, 23, thereby causing the deposition of a thin film onto the substrate.

A remote plasma unit (RPU, not shown) may be disposed above the reaction chambers 12, 22. A cleaning gas may be supplied to the RPU from a cleaning gas source (not shown), thereby turning into gas radicals, gas ions, or both (reactive gases).

A substrate processing apparatus further includes a shared exhaust unit 51 configured to exhaust the main gas from the reaction chambers 12, 22. Two exhaust gas lines 16, 26 may be configured to fluidly couple the shared exhaust unit 51 to the reaction chambers 12, 22. Further, two dilution gas lines 17, 27 may be configured to provide a dilution gas into the exhaust gas lines 16, 26.

The shared exhaust unit 51 may comprise a shared valve 52 configured to control a flow rate of an exhaust gas and a shared vacuum pump 53 fluidly coupled to the shared valve 52. The shared valve 52 may comprise an auto pressure control valve.

The substrate processing apparatus may further include dilution gas valves 37, 47, which are configured to control a flow rate of the dilution gas. The flow rate of the dilution gas may be configured to be controlled to keep the shared valve 52 open, thereby exhausting the gases continuously.

The substrate processing apparatus may further include seal gas lines 15,25 disposed in a bottom of the reaction chambers 12, 22. The seal gas lines may be configured to provide a seal gas into the reaction chambers 12, 22. The seal gas may be used to prevent a plasma from introducing into a susceptor lifting mechanism (not shown).

The dilution gas valves 37, 47 may be configured to control the flow rate of the dilution gas to exceed the total flow rate of the main gas and seal gas. The flow rate of the main gas and seal gas may be low, thereby reducing particles in the reaction chambers 12, 22. The total flow rate of the dilution gas, the main gas, and the seal gas may be 100 sccm to 100 slm to keep the shared valve 52 open.

The substrate processing apparatus may further include a plurality of gate valves 19, 29, each of which is connected to walls of the reaction chambers 12, 22 respectively. The substrate transfer robot 3 may transfer a substrate 18, 28 between the reaction chamber and the substrate transfer chamber through the gate valves 19, 29. Each of the gate valves 19, 29 may be configured to be opened when the substrate is being transferred from the substrate transfer chamber to the reaction chamber and vice versa. The dilution gas may be continuously supplied to keep the shared valve 52 open when the gate valves are opened, thereby exhausting the gases continuously.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A substrate processing apparatus, comprising:
a plurality of reaction chambers;
a plurality of gas supply units configured to provide the reaction chambers with a main gas;
a shared exhaust unit configured to exhaust the main gas from the plurality of reaction chambers;
a plurality of exhaust gas lines configured to fluidly couple the shared exhaust unit to the plurality of reaction chambers; and
a plurality of dilution gas lines configured to provide a dilution gas into the plurality of exhaust gas lines.

2. The substrate processing apparatus according to claim 1, wherein the shared exhaust unit comprises:
a shared valve configured to control a flow rate of an exhaust gas; and
a shared vacuum pump fluidly coupled to the shared valve.

3. The substrate processing apparatus according to claim 1, further comprising a dilution gas valve configured to control a flow rate of the dilution gas.

4. The substrate processing apparatus according to claim 3, wherein the flow rate of the dilution gas is configured to be controlled to keep the shared valve open.

5. The substrate processing apparatus according to claim 1, further comprising a plurality of seal gas lines disposed in a bottom of the reaction chambers and configured to provide a seal gas into the reaction chambers.

6. The substrate processing apparatus according to claim 5, wherein the dilution gas valves are configured to control the flow rate of the dilution gas to exceed the total flow rate of the main gas and seal gas.

7. The substrate processing apparatus according to claim 6, wherein the total flow rate of the dilution gas, the main gas, and the seal gas is 100 sccm to 100 slm.

8. The substrate processing apparatus according to claim 1, wherein the main gas comprises a process gas, carrier gas, and dilution gas.

9. The substrate processing apparatus according to claim 1, further comprising a plurality of gate valves connected to a wall of the reaction chambers.

10. The substrate processing apparatus according to claim 9, further comprising a substrate transfer chamber connected to the gate valves.

11. The substrate processing apparatus according to claim 10, further comprising a substrate transfer robot disposed within the substrate transfer chamber for transferring a substrate between the reaction chamber and the substrate transfer chamber through the gate valve.

12. The substrate processing apparatus according to claim 11, wherein the gate valves are configured to be opened when the substrate is being transferred from the substrate transfer chamber to the reaction chamber and vice versa.

13. The substrate processing apparatus according to claim 1, further comprising a plurality of susceptors positioned within the reaction chambers and arranged to support the substrate.

14. The substrate processing apparatus according to claim 1, wherein the gas supply units comprise a shower plate arranged to face the susceptor.
